(19) United States
(12) Patent Application Publication
(10) Pub. No.: US 2002/0116681 A1
(43) Pub. Date: Aug. 22, 2002

(54) Decoder, system and method for decoding trubo block codes

(75) Inventors: Ofer Amrani, Tel Aviv (IL); Meir Ariel, Tel Aviv (IL)

Correspondence Address: G. E. EHRLICH LTD., c/o ANTHONY CASTORINA, SUITE 207, 2001 JEFFERSON DAVIS HIGHWAY, ARLINGTON, VA, 22202, US

(73) Assignee: Cute Ltd.

(21) Appl. No.: 09/748,779

(22) Filed: Dec. 27, 2000

(51) Int. Cl. H03M 13/00; H03M 13/03

(52) U.S. Cl. 714/792; 714/755

(57) ABSTRACT

A turbo block codes decoder for decoding turbo block codes presented in a matrix form and having at least two dimensions is provided. The turbo block codes decoder including: (a) a first decoder for soft decoding individual first block codes along a first dimension of the matrix for generating first codewords in the first dimension of the matrix; (b) a reliability measure calculator for calculating reliability measures of the first codewords in the first dimension of the matrix, thereby forming soft valued vectors along a second dimension of the matrix; and (c) a second decoder for soft decoding individual vectors of the soft valued vectors along the second dimension of the matrix, for generating second codewords in the second dimension of the matrix, the second codewords being a decoded output of the turbo block codes decoder.

### FIELD AND BACKGROUND OF THE INVENTION

The present invention relates to a decoder and to a system and method utilizing same for decoding turbo block codes, such as for example, turbo block codes of a multi-dimensional matrices.

In wire-line and wireless digital communication systems, error correction codes are often employed to protect the transmitted information from error, in particular to overcome noise and distortion that may be introduced over a communication channel. It is well known that for different types of digital data, different bit error rates are acceptable/required. For example, while for digital voice data, a bit error rate of 10⁻³ is acceptable, a bit error rate of 10⁻⁷−10⁻⁸ is required for other, more sensitive, applications in which digital data is communicated, such as in the communication of image data, e.g., TV.

Furthermore, when data is transmitted in coded frames, the preferred performance criterion is usually minimum decoded Frame Error Rate (FER) (rather than minimum decoded bit error rate).

Still furthermore, minimizing the FER has great importance also in systems where re-transmission of the data is executed. Typically, retransmission utilizes a CRC mechanism for identifying erroneously decoded frames.

Multi-dimensional Turbo Block Codes (TBC) are good candidates for use in such retransmission systems, as they can achieve low FER performance. Unfortunately, however, the computational complexity entailed by decoding such codes may be intolerable. In particular, decoding is generally carried out using iterative methods which are typically computationally complex. Hence, there is a need for a high speed, low complexity/size solution to the problem of decoding TBC.

Another problem associated with conventional iterative decoding is to find efficient stopping algorithms. Such algorithms are aimed at determining when to abort the decoding process, i.e., deciding when the processed frame is ready to be outputted from the decoder.

In each iteration of a conventional iterative process, reliability metrics (also called soft outputs or soft metrics) are computed for all of the data bits. A vector of such soft metrics may be used as a priori information for the next iteration. It is generally assumed that the reliability of the bits is improved with increasing number of iterations. The amount of processing required for achieving satisfactory bit reliability using conventional reiterative methods depends on the specific channel conditions. The channel conditions may vary in time, which essentially means that different frames may be corrupted differently, hence requiring a different number of iterations.

Several approaches have been suggested over the years to overcome the above-related problems, as follows:

1. The use of long block codes (one-dimensional) with large minimum distance. The problem raised by this approach is that the computational complexity associated with soft-decision decoding of such codes is known to be so high so as to render the approach unfeasible. This approach is described in F. J. MacWilliams et al. “The theory of error-correcting codes”, Elsevier-North Holland, 1997, the contents of which are hereby incorporated by reference.

2. The maximum likelihood soft-decision decoding of TBC is the optimal approach to achieve minimum FER performance. Unfortunately, it too is computationally far too complex to be feasible for implementation with practical frame lengths.

3. Another method comprises using TBC with iterative decoding. Such a technique is described in U.S. Pat. No. 5,563,897 to Pyndiah et al., entitled “Method for detecting information bits processed by concatenated block codes”, the contents of which are hereby incorporated by reference. The problems with this approach are the following: (i) the method aims at reducing the Bit Error Rate (BER) rather than the FER; and (ii) the method again is one of high computational complexity—in each iteration a complex procedure is used to compute the reliability of each of the bits in the received vector.

4. A further known approach is the use serial or parallel concatenated convolutional codes (turbo codes). The problems with this approach are the same as those of the Pyndiah approach above.

There is thus a widely recognized need for, and it would be highly advantageous to have, a decoder of multi-dimensional matrices of turbo block codes devoid of the limitations associated with the prior art.

### SUMMARY OF THE INVENTION

Embodiments of the present invention solve the above problems with the prior art by utilizing a novel turbo block decoder.

Unlike conventional iterative TBC decoders, embodiments of the present invention provide a decoder that performs turbo block decoding in a non-iterative manner. As such, the TBC decoder of the present invention can be utilized to rapidly and accurately decode turbo block codes as well as to substantially reduce iterative steps in an iterative decoder co-operating therewith.

According to one aspect of the present invention there is provided a turbo block codes decoder for decoding turbo block codes being inputted in a matrix having at least two dimensions, the turbo block codes decoder comprising: (a) a first decoder for soft decoding individual first block codes along a first dimension of the matrix for generating first codewords in the first dimension of the matrix; (b) a reliability measure calculator for calculating reliability measures of the first codewords in the first dimension of the matrix, thereby forming soft valued vectors along a second dimension of the matrix; and (c) a second decoder for soft decoding individual vectors of the soft valued vectors along the second dimension of the matrix, for generating second codewords in the second dimension of the matrix, the second codewords being a decoded output of the turbo block codes decoder.

According to another aspect of the present invention there is provided a turbo block codes decoder for decoding turbo block codes being inputted in a matrix having at least two dimensions, the turbo block codes decoder comprising: (a) a first decoder for soft decoding individual first block codes along a first dimension of the matrix for generating first codewords in the first dimension of the matrix; (b) a first reliability measure calculator for calculation a reliability of the first codewords in the first dimension of the matrix, thereby forming first soft valued vectors along a second dimension of the matrix; (c) a second decoder for soft decoding individual vectors of the first soft valued vectors along the second dimension of the matrix for generating second codewords in the second dimension of the matrix, the second codewords being a first decoded candidate output of the turbo block codes decoder; (d) a third decoder for soft decoding individual second block codes along the second dimension of the matrix for generating third codewords in the second dimension of the matrix; (e) a second reliability measure calculator for calculation a reliability of the third codewords in the second dimension of the matrix, thereby forming second soft valued vectors along the first dimension of the matrix; (f) a fourth decoder for soft decoding individual vectors of the second soft valued vectors along the first dimension of the matrix for generating fourth codewords in the first dimension of the matrix, the fourth codewords being a second decoded candidate output of the turbo block codes decoder; and (g) a selector for selecting among the first and the second decoded candidate outputs.

According to yet another aspect of the present invention there is provided a turbo-block codes decoder comprising a non-iterative decoder and an iterative decoder connected such that an output at each step of the iterative decoder is used as an input to the non-iterative decoder to produce an output matrix, wherein the non-iterative decoder is operable to determine whether the output matrix is a legitimate codeword of a turbo-block code being used, and further wherein a result of the determination signals the iterative decoder to carry out a further iteration step if the output matrix is not a legitimate codeword.

According to still further features in the described preferred embodiments the non-iterative decoder including: (a) a first decoder for soft decoding individual first block codes along a first dimension of the matrix for generating first codewords in the first dimension of the matrix; (b) a reliability measure calculator for calculating reliability measures of the first codewords in the first dimension of the matrix, thereby forming soft valued vectors along a second dimension of the matrix; and (c) a second decoder for soft decoding individual vectors of the soft valued vectors along the second dimension of the matrix, for generating second codewords in the second dimension of the matrix, the second codewords being a decoded output of the turbo block codes decoder.

According to still further features in the described preferred embodiments the non-iterative decoder further including: (d) a declarator for declaring a decoding failure if the decoded output fails to comply with a legitimate codeword in the turbo block code.

According to still further features in the described preferred embodiments the non-iterative decoder further including: (d) a first dimension syndrome calculator for determining whether decoded bits of the second codewords form legitimate codewords in the first dimension.

According to further features in preferred embodiments of the invention described below,the turbo block codes decoder further comprising: (d) a declarator for declaring a decoding failure if the decoded output fails to comply with a legitimate codeword in the turbo block code.

According to still further features in the described preferred embodiments the turbo block codes decoder further comprising: (d) a first dimension syndrome calculator for determining whether decoded bits of the second codewords form legitimate codewords in the first dimension.

According to still further features in the described preferred embodiments the first dimension is a row dimension and the second dimension is a column dimension.

According to still further features in the described preferred embodiments the reliability measures of the first codewords in the first dimension of the matrix is given by: f(yᵢ−,ĉᵢ−) wherein, yᵢ− is a first dimension line i, ĉhd i− is a first decoded codeword i, whereas f(yᵢ−,ĉᵢ−) is a function of the Euclidean distance between yᵢ− and ĉᵢ− as defined by: d(yᵢ−,ĉᵢ−).

According to still further features in the described preferred embodiments a bit reliability of a decoded bit i,j, ĉ_{i,j} of the first codeword ĉᵢ− is given by: F(yᵢ−,ĉᵢ−,ĉ_{i,j}), wherein the F(yᵢ−,ĉᵢ−,ĉ_{i,j}) is a function of ĉ_{i,j} and a reliability f(yᵢ−,ĉᵢ−) of the first dimension line yᵢ−.

According to still further features in the described preferred embodiments the first decoder and the second decoder are the same decoder.

According to still further features in the described preferred embodiments the first decoder and the second decoder are different decoders.

According to still further features in the described preferred embodiments there is provided a system of turbo block codes decoders including the turbo block codes decoder described above connected with a second identical turbo block codes decoder being designed and configured for decoding a transposition of the inputted matrix.

According to still further features in the described preferred embodiments the system further comprising an output selector for selecting between the outputs of either one of the turbo block codes decoders.

According to still further features in the described preferred embodiments the system further comprising an output selector for selecting between an output of either one of the turbo block codes decoders and an uncorrectable error flag.

According to still further features in the described preferred embodiments the output selector is operable to select according to the following rules: (i) if only one of the turbo block codes decoders outputs a legitimate codeword—select the legitimate codeword; and (ii) if both the turbo block codes decoders output legitimate codewords—select the output characterized by a minimum Euclidean distance from the inputted matrix.

According to still further features in the described preferred embodiments if neither of the outputs are legitimate codewords, the output selector is operable to indicate a decoding failure.

According to still further features in the described preferred embodiments if neither of the outputs are legitimate codewords, the output selector is operable to request reinput of the turbo block codes.

According to still further features in the described preferred embodiments if neither outputs are legitimate codewords, the output selector is operable to select the output having minimum Euclidean distance from inputted matrix.

According to still further features in the described preferred embodiments if neither outputs are legitimate codewords, the output selector is operable to select the output having fewer bit errors relative to a bit-wise hard decision decoding of the inputted matrix.

According to still further features in the described preferred embodiments if neither outputs are legitimate codewords, the output selector is operable to select a combination of bits from the two outputs to form an optimized combination result.

According to still further features in the described preferred embodiments there is provided a system for turbo block codes decoding, including an iterative turbo block decoder and the turbo block codes decoder described above, being connected thereto and operable to supply the iterative turbo block decoder with a signal to perform a further decoding iteration whenever an output of the iterative turbo block decoder does not give rise to a legitimate codeword in the turbo block codes decoder.

According to still another aspect of the present invention there is provided a method of decoding turbo block codes being inputted in a matrix having at least two dimensions, the method comprising the steps of: (a) decoding individual first block codes along a first dimension of the matrix for generating first codewords in the first dimension of the matrix; (b) calculating reliability measures of the first codewords in the first dimension of the matrix, thereby forming soft valued vectors along a second dimension of the matrix; and (c) soft decoding individual vectors of the soft valued vectors along the second dimension of the matrix, for generating second codewords in the second dimension of the matrix, the second codewords being a first decoded candidate output.

According to still further features in the described preferred embodiments the method further comprising the step of: (d) declaring a decoding failure if the decoded candidate output fails to comply with a legitimate codeword in the turbo block codes.

According to still further features in the described preferred embodiments the method further comprising the step of: (d) determining whether decoded bits of the second codewords form legitimate codewords in the first dimension.

According to still further features in the described preferred embodiments the first dimension is a row dimension and the second dimension is a column dimension.

According to still further features in the described preferred embodiments the reliability measures of the first codewords in the first dimension of the matrix is given by: f(yᵢ−,ĉᵢ−), wherein yᵢ− is a first dimension line i, ĉᵢ− is a first codeword i, whereas f(yᵢ−,ĉᵢ−) is a function of an Euclidean distance between yᵢ− and ĉᵢ− as defined by: d(yᵢ−,ĉᵢ−).

According to still further features in the described preferred embodiments a bit reliability of a decoded bit i,j, ĉ_{i,j} of the first codeword ĉᵢ− is given by: F(yᵢ−,ĉᵢ−,ĉ_{i,j}), wherein the F(yᵢ−,ĉᵢ−,ĉ_{i,j}) is a function of ĉ_{i,j} and a reliability f(yᵢ−,ĉᵢ−) of the first dimension line yᵢ−.

According to still further features in the described preferred embodiments the method further comprising the steps of: (d) transposing the matrix and repeating steps (a)-(c) to thereby generate a second decoded candidate output.

According to still further features in the described preferred embodiments the method further comprising the step of: (e) selecting among the first and the second decoded candidate outputs.

According to still further features in the described preferred embodiments the method further comprising the step of: (e) selecting among the first and the second decoded candidate outputs and an uncorrectable error flag.

According to still further features in the described preferred embodiments the method further comprising the step of: (e) indicating a decoding failure if neither decoded candidate outputs are legitimate codewords.

According to still further features in the described preferred embodiments the method further comprising the step of: (e) request reinput of the turbo block codes if neither of the decoded candidate outputs are legitimate codewords,.

According to still further features in the described preferred embodiments the method further comprising the step of: (e) selecting the decoded candidate output having minimum Euclidean distance from the turbo block codes inputted in the matrix if neither of the outputs are legitimate codewords.

According to still further features in the described preferred embodiments the method further comprising the step of: (e) selecting the decoded candidate output having fewer bit errors relative to a bit-wise hard decision decoding of the inputted matrix if neither outputs are legitimate codewords.

According to still further features in the described preferred embodiments the method further comprising the step of: (e) selecting a combination of bits from the first and the second decoded candidate outputs to form an optimized combination result if neither outputs are legitimate codewords.

According to still further features in the described preferred embodiments step (b) is effected according to the following rules: (i) if only one of the turbo block codes decoder units outputs a legitimate codeword—select the legitimate codeword; and (ii) if both the turbo block codes decoder units output legitimate codewords—select the output characterized by a minimum Euclidean distance from the inputted matrix.

According to still another aspect of the present invention there is provided a method for iteratively decoding a turbo block encoded message, the method comprising the steps of: (a) carrying out an iterative turbo-block decoding step to produce a first output; (b) decoding the first output non-iteratively to produce an output matrix; and (c) determining whether the output matrix is a legitimate codeword in the turbo block code.

According to still further features in the described preferred embodiments the method further comprising the step of: (d) returning to the iterative decoding step if the output matrix is not legitimate or terminating the iterative decoding if the output matrix is a legitimate codeword in the turbo block code.

The present invention successfully addresses the shortcomings of the presently known configurations by providing a decoder capabale of performing turbo block decoding in a non-iterative manner.

Implementation of the method and system of the present invention involves performing or completing selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified diagrammatic representation of turbo block encoded data;

FIG. 2 is a simplified block diagram showing a digital communication system using a turbo block code;

FIG. 3 is a simplified diagram of a turbo block decoder according to a preferred embodiment of the present invention;

FIG. 4 is a simplified diagram of a soft decision decoder for use with the embodiment shown in FIG. 3;

FIG. 5 is a generalized flow diagram showing the operation of the turbo block decoder of FIG. 3;

FIG. 6 is a generalized block diagram of a turbo block decoder according to a preferred embodiment of the present invention;

FIG. 7 is a generalized flow diagram showing the operation of the turbo block decoder of FIG. 6;

FIG. 8 is a generalized block diagram of a system including a non-iterative turbo block decoder being used in conjunction with a conventional iterative turbo block decoder according to a preferred embodiment of the present invention; and

FIG. 9 is a generalized flow diagram showing operation of the system of FIG. 8.

### DESCRIPTION OF THE PREFERRED EMBODIMENTS

The present invention is of a decoder and a decoding system and method which can be utilized to decode turbo block codes. Specifically, the present invention can be used to non-iteratively decode turbo block codes arranged in, for example, multi dimensional matrices, thus enabling rapid, non-iterative, decoding of long codes while still providing highly accurate decoding results.

The principles and operation of the present invention may be better understood with reference to the drawings and accompanying descriptions.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

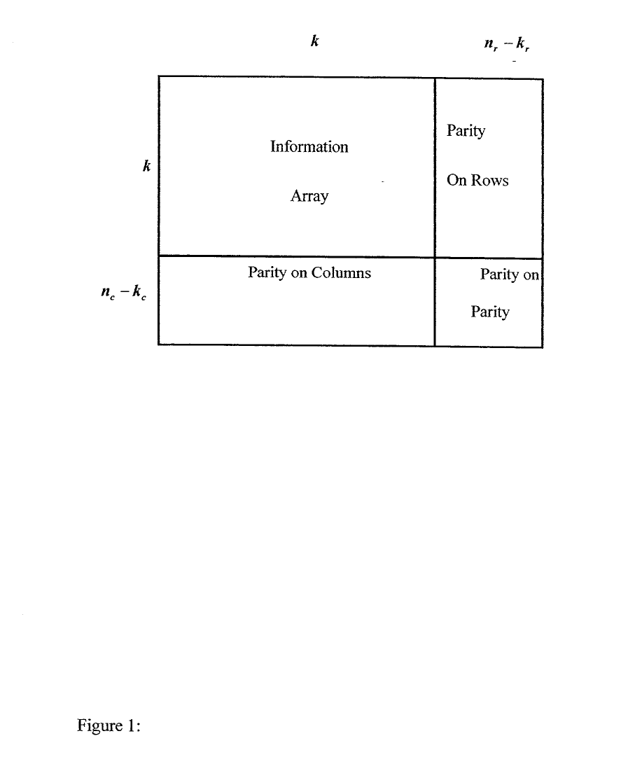

Reference is now made to FIG. 1, which is a diagrammatic representation of a two-dimensional turbo block code Cₚ. In this case, the data is inputted into a two-dimensional information array or data array 10 having a row (first dimension) length kᵣ and a column (second dimension) length k_{c}. Each row has a series of parity bits (region 12) as does each column (region 14). In addition, a region 16 is defined having parity bits for the row and column parity regions 12 and 14. Including the parity bits, the total row length is nᵣ and the total column length is n_{c}, giving nᵣ-kᵣ parity bits per row, and n_{c}-k_{c} parity bits per column.

The two-dimensional turbo block code (TBC) Cₚ=Cᵣ×C_{c} contains all the matrices whose columns are codewords in C_{c} and whose rows are codewords in Cᵣ. The parameters of this TBC are given by [nₚ,kₚ,dₚ]=[nᵣn_{c},kᵣk_{c},dᵣd_{c}], where n denotes the length, k, the dimension, and d, the minimum Hamming distance of the corresponding code.

Without loss of generality, the mapping of a bit b onto the Euclidean space is taken to be:

c=(−1)^{b} (1)

(corresponding to binary phase shift keying modulation). The symbol c is thus called the Euclidean image of b. Hereinbelow, when referring to a codeword, what is intended is the Euclidean image of the codeword in accordance with the mapping in (1).

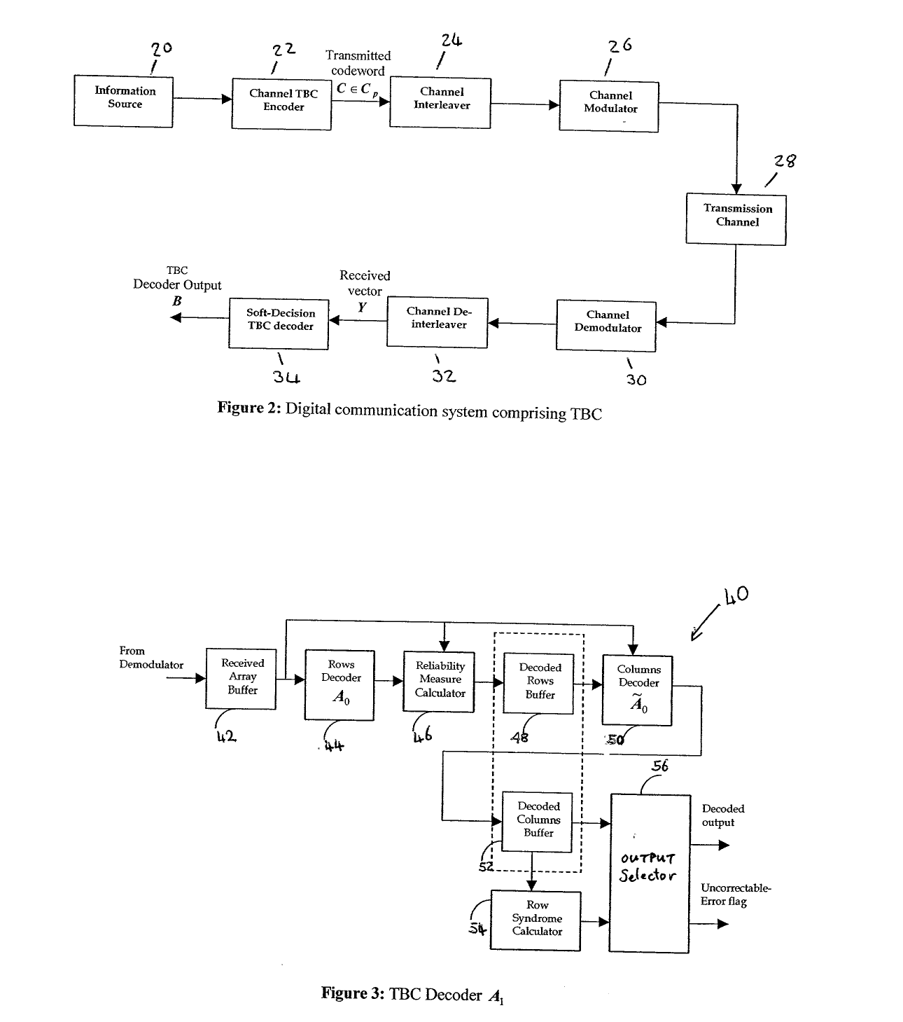

Reference is now made to FIG. 2, which is a simplified diagram showing a communication channel and TBC encoding, to which the present invention may be applied.

Data for transmitting over the channel issues from a data source 20 and is encoded by a channel TBC encoder 22 into a series of transmitted codewords CεCₚ. The channel codewords are interleaved by a channel interleaver 24 and modulated for transmission by a channel modulator 26. The modulated signal is then transmitted over a channel 28 where it is subjected to noise and distortion such that a noisy and distorted signal is received for demodulation at a channel demodulator 30. The demodulated signal is then de-interleaved at a channel de-interleaver 32 into a received matrix Y which is decoded using a soft decision TBC decoder 34 to produce an output matrix B.

As discussed hereinabove, a codeword CεCₚ is an nᵣ×n_{c} matrix with entries taken from the set {+1,−1}. C is transmitted over the transmission channel 28 which may be an additive white Gaussian noise (AWGN) channel to give rise to Y which is, as mentioned above, the received noisy version of C. For the mapping given by equation (1) above (for binary PSK), the minimum squared Euclidean distance (SED) of the TBC is given by 2²·dₚ=4dᵣd_{c}, which, in turn, means that correct decoding is guaranteed as long as d²(Y,C)<dᵣd_{c}, where d(●,●) denotes the Euclidean distance. A decoder that achieves this correction capability is known as a bounded-distance decoder.

According to one aspect of the present invention and as specifcally shown in FIG. 3, there is provided a decoder for decoding turbo block codes which is referred to hereinunder as TBC decoder 40.

TBC decoder 40 includes a received array buffer 42 for storing received arrays Y prior to processing. Received buffer array 42 is connected to a row decoder 44 which is operable to decode rows of the array Y according to algorithm Ã₀ which will be described below. A reliability measure calculator 46 is connected to the output of row decoder 44 to provide a measure of the decoding reliability as will be described below, and the decoded rows are then passed to a decoded rows buffer 48 connected to the output of the reliability measure calculator 46.

A matrix of the row codewords is built up and probabilities are assigned thereto to form a new matrix U. A columns decoder 50 is connected to the output of the decoded rows buffer 48 and is operable to decode the columns of the new matrix U, using the algorithm Ã₀ which will be described below.

The output of columns decoder 50 is then passed to a columns buffer 52, which is connected to a row syndrome calculator 54 to determine whether legitimate codewords appear in the rows of the decoded matrix. Columns buffer 52 is also connected to output selector 56, which is operable to produce either a final decoded output or a flag indicating that the signal has not been correctly decoded, depending upon the determination of row syndrome calculator 54.

The above algorithm will be described in greater detail below with respect to FIG. 6.

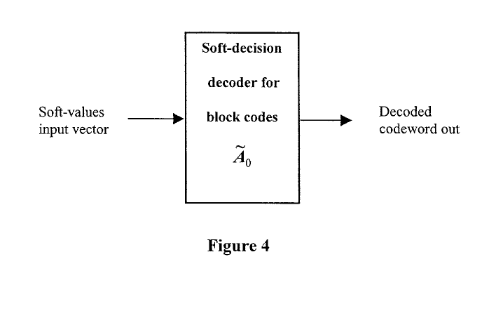

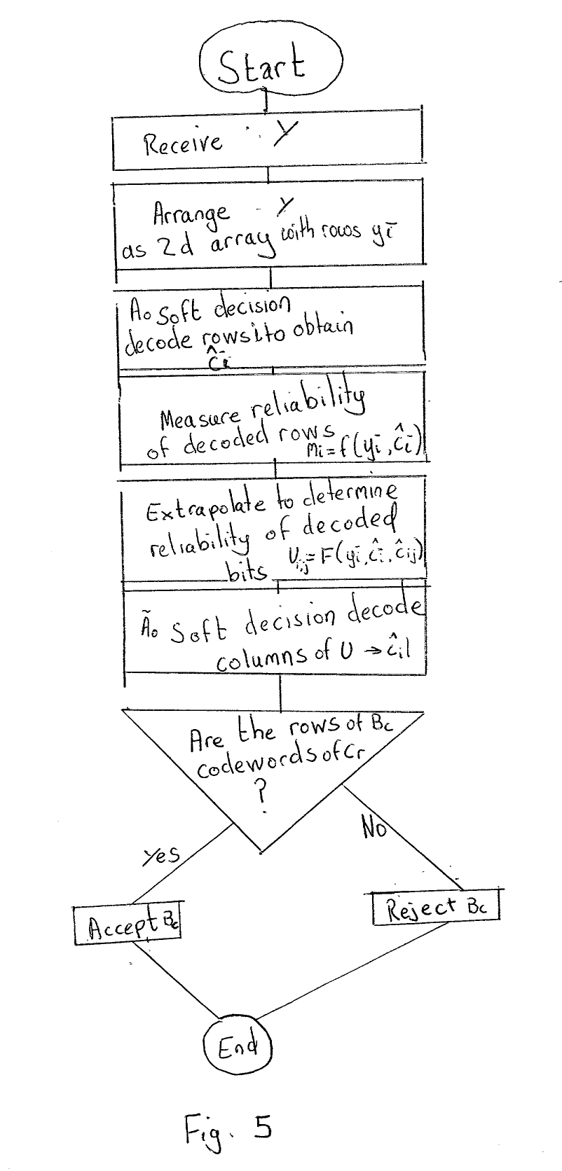

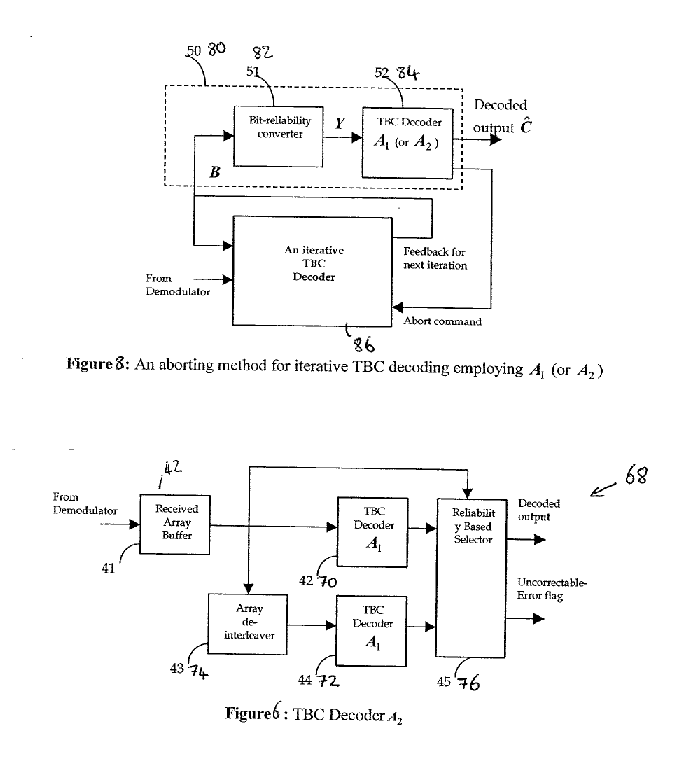

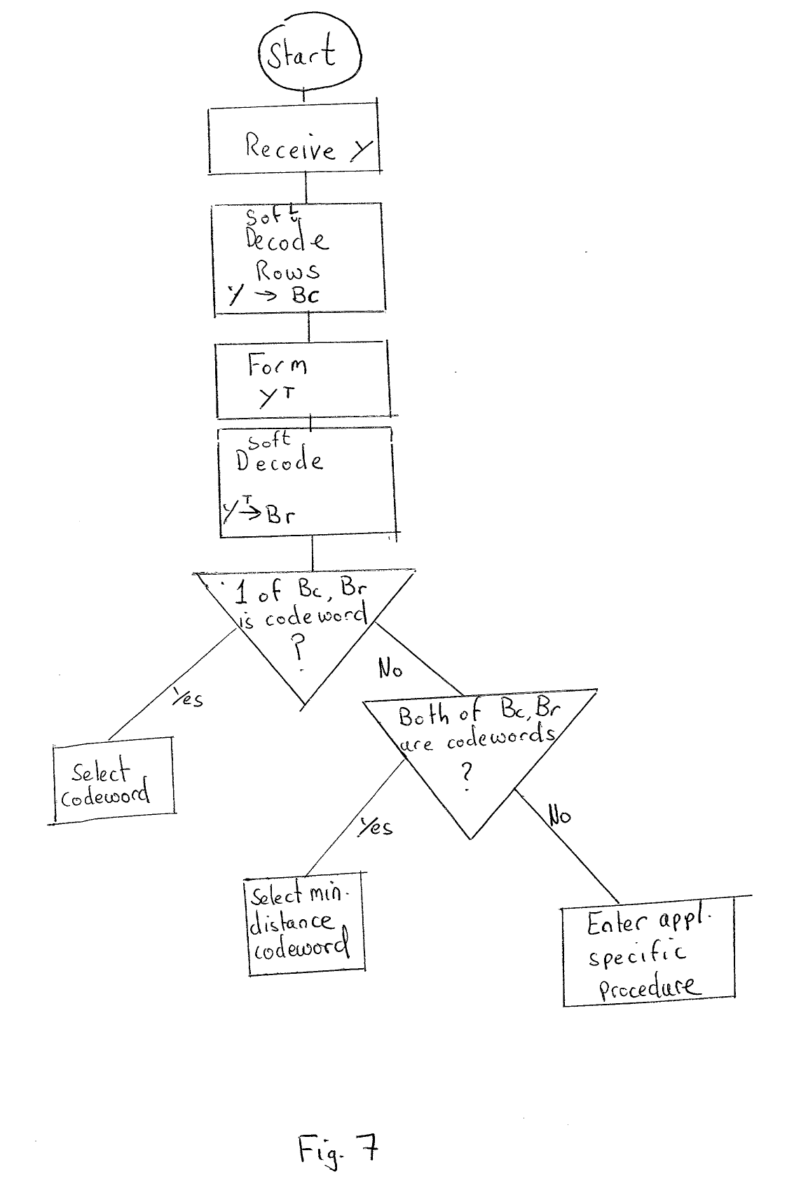

Reference is now made to FIG. 4, which is a simplified flow diagram showing algorithm Ã₀ mentioned above. The decoder Ã₀ is a soft decision decoder for block codes suitable for decoding the row code Cᵣ and the column code C_{c}. The decoder accepts a vector of soft values, performs soft decision decoding, and outputs a decoded codeword. The decoder may be any maximum-likelihood soft-decision decoder, or sub-optimal soft-decision decoder known in the art. It should not necessarily be the same decoder for the rows and the columns.

Reference is now made to FIG. 5, which is a simplified flow diagram showing the preferred operation of TBC decoder 40 of the present invention.

The turbo block encoded message is received and is arranged as a two-dimensional array. Soft decision encoding is used to decode the rows using algorithm Ã₀ such that each of the n_{c} rows, yᵢ−, of Y is decoded to obtain a codeword ĉᵢ−. A measure is then taken of the reliability of decoding of the rows by assigning to each row the following reliability metric mᵢ=f(yᵢ−,ĉᵢ−), where f(a,b) is a non-negative reliability measure of the variables a and b. A two-dimensional array is formed from (ĉ₁−,ĉ₂−,ĉ₃−, . . . ĉₙ_{_{c}}−)^{T} and is denoted hereinbelow as Y.

The row reliability is extrapolated to give a bit reliability, as follows. Let U be an array whose entries are the reliabilities of the bits in Ŷ. Each (i,j) entry of U being computed as u_{i,j}=F(yᵢ−,ĉᵢ−,ĉ_{i,j}), where ĉ_{i,j} is the bit in position j of the row codeword ĉᵢ−, and F(.,.,.) is a function representing the reliability of ĉ_{i,j}. The algorithm allows some degree of freedom in the definition of F(.,.,.). Obviously, the particular choice of F(.,.,.) affects both the computational complexity and the FER performance. The trade off between those two parameters depends on the system requirements. A particular choice for F(.,.,.) is described below although the skilled person will be aware that other possibilities exist.

Algorithm Ã₀ is then used to soft decode the columns of U, Ã₀ being an algorithm that may be, but is not necessarily, the same as that used for decoding the rows. Decoding is carried out on each of the nᵣ columns, uⱼ^{|}, of U. For each column a codeword ĉᵢ^{|} is thereby obtained. The matrix containing the nᵣ decoded columns ĉᵢ^{|} is denoted B_{c}.

The rows of B_{c} are then checked to see whether they are legitimate codewords of Cᵣ, and if so the decoded result B_{c} is accepted as the output. If not it is rejected. This is done as follows: a two-dimensional array (consisting of the column vectors) B_{c}=(ĉ₁^{|},ĉ₂^{|},ĉ₃^{|}, . . . ĉₙ_{ᵣ}^{|}) is obtained. If each and every one of the rows of B_{c} is a codeword in Cᵣ as determined by the row syndrome calculator 54, then B_{c} is a codeword in the TBC Cₚ, and thus B_{c} may be selected as the output of row decoder 44. Otherwise, B_{c} is not a codeword and the uncorrectable-error flag is set by the output selector 56.

The operation of TBC decoder 40 of the present invention is hereinafter referred to as algorithm A₁. The reliability measure of the decoded rows, referred to above, may be taken to be:

$$f ( {y}_{\overline{i}} , {\hat{c}}_{\overline{i}} ) min \{ 1 , \frac{d ( {y}_{\overline{i}} , {c}_{\overline{i}} )}{\sqrt{{d}_{r}}} \} , \qquad ( 2 )$$

and the reliability measure of the bits may be taken to be:

F(yᵢ−,ĉᵢ−,ĉ_{i,j})=ĉ_{i,j}(1−mᵢ), (3)

in which case A₁ is a bounded-distance soft-decision decoder that achieves the guaranteed Euclidean error correction radius of the TBC Cₚ. This is achieved even though the complexity involved in computing equations (2) and (3) is low).

Returning to FIG. 3, received array buffer 42 preferably holds channel measurements corresponding to the received matrix. If u_{i,j} is taken to be as in equation (3) above then RAM used for buffer 42 may be reused for rows buffer 48. Similarly, decoded rows buffer 48 and decoded columns buffer 52 may be implemented as a single physical block of RAM, depending on the specific application. However, it will be appreciated that better performance can be achieved by designing a high speed pipe-line implementation, by for example, using three different RAMs for separate buffers 42, 48 and 52.

According to another aspect of the present invention and as specifcally shown in FIG. 6, there is provided a turbo block code decoder which is referred to hereinunder as TBC decoder 68.

Components which are identical to those shown above are given the same reference numerals and are not referred to again except as necessary for an understanding of this aspect of the present invention.

As specifically shown in FIG. 6, TBC decoder 68 includes a received buffer array 42 which is connected to a first TBC decoder 70 executing algorithm A₁ and is preferably of the same type as that shown in FIG. 3. Received array buffer 42 is additionally connected to a second TBC decoder 72 which is of the same type, but this time it is connected via an array de-interleaver 74. Received array buffer 42, and TBC decoders 70 and 72 are connected to a reliability based selector 76 which has two outputs, a decoded output for an accepted decoded result and an uncorrectable error flag.

Decoder 68 is operative to provide turbo block decoding according to an algorithm A₂. The previously described algorithm A₁ is formulated such that the rows are decoded before the columns. This is merely an arbitrary order and it may be advantageous to decode the columns before the rows, which is equivalent to using A₁ for decoding Y^{T}, where Y^{T} stands for a transposed array of Y, as above. This observation serves as the basis for the decoder A₂ which preferably has an improved FER performance relative to A₁ although at a slight increase in decoding complexity.

Operation of decoder 68 is described with reference to FIG. 7 which is a simplified flow diagram of algorithm A₂.

Following input, a received array Y is decoded using algorithm A₁ at decoder 70 to give a candidate array of bits B_{c}.

The received array Y is then transposed using array interleaver 74 to produce transposed array Y^{T}. The transposed array Y^{T} is then decoded using algorithm A₁ at decoder 72 to obtain a candidate codeword of bits Bᵣ.

A reliability based selector then selects either B_{c}, or Bᵣ, as the output of A₂ according to the following selection rules:

(i) If only one of the candidate arrays is a codeword in Cₚ: select the array that is a codeword;

(ii) If the two candidate arrays are codewords: select the one at minimum Euclidean distance from the received array Y;

(iii) If neither candidate array is a codeword then adopt a predetermined application specific procedure which is selected to be appropriate for the current application.

Suitable application specific procedures for rule (iii) above include the following: in an Automatic Repeat Request (ARQ) system, an incorrectable error may be flagged such that the transmitter is asked to retransmit the codeword. If, however, no retransmissions are possible, then one of the following rules can be applied:

(i) select the array closest to Y;

(ii) select the array with the smaller amount of bit errors relative to Ŷ, the bit-wise hard decisions of Y; and

(iii) some combination of bits from both B_{c} and Bᵣ may be taken according to a joint reliability measure.

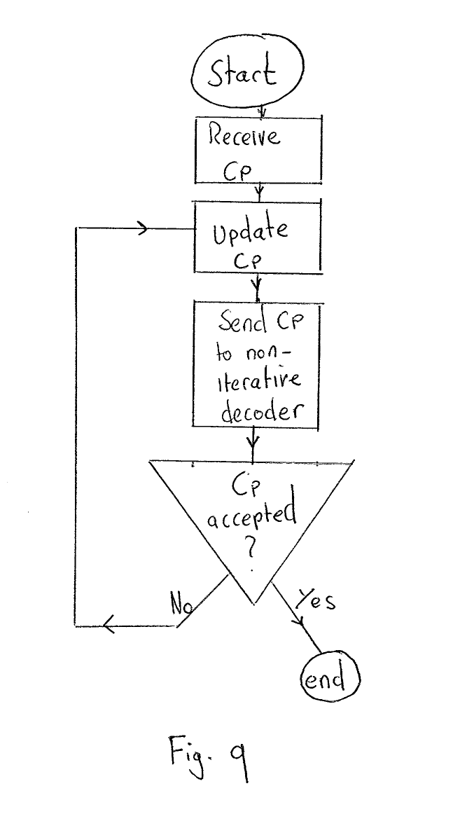

According to yet another aspect of the present invention and as specifically shown in FIG. 8, there is provided a turbo block decoder which functions as an iteration aborter for an iterative decoder and which can be included along with an iterative decoder in a combined decoding system.

Components which are identical to those shown above are given the same reference numerals and are not referred to again except as necessary for understanding this aspect of the present invention.

As specifically shown in FIG. 8, an iteration aborter 80 includes a bit reliability converter 82 and a TBC decoder 84. TBC decoder 84 may use either of algorithms A₁ and A₂ to determine whether a legitimate codeword has been formed by an iterative TBC decoder 86 connected to iteration aborter 80. TBC decoder 86 may be any iterative TBC converter known in the art. Iteration aborter 80 is connected such that the incorrectable error flag supplies the iterative decoder with a signal to continue operating, or alternatively serve as a signal for iteration to come to an end. In the diagram shown, the decoded output is taken from the iteration aborter 80.

According to this aspect of the present invention, the decoder of either of the previous embodiments, which gives a single step definitive answer as to whether decoding is possible or not, may be used in conjunction with iterative TBC decoder 86 to determine when the iterations should stop. This is useful in that in order to speed up the iterative TBC decoder 86 it is preferable to keep the number of iterations as small as possible while obtaining the desirable performance. Furthermore, as will be explained below, the non-iterative decoder is able to correct the output of the iterative decoder to a certain extent, thereby reducing the number of iteration steps necessary even further.

Either one of decoding algorithm A₁ and decoding algorithm A₂ can be used for stopping the iterative process as soon as successful decoding is attained.

This combined decoding process is based on the following observation: it is generally assumed that the iterative process enhances the reliability (signal to noise ratio) of the processed bits. Consequently, after some iterations the array B of bit reliabilities, properly interpreted as Euclidean distances, will most likely be close in a Euclidean sense to a legitimate codeword Ĉ in Cₚ. Whenever this distance is smaller than \sqrt{dᵣd_{c}}, and assuming the use of the reliability measures as given by the above equations (2) and (3) above, then A₁ or A₂ will result in the desired codeword Ĉ (due to their bounded-distance property). This result may be achieved after a number of iterations depending on the level of distortion and noise in the signal.

Reference is now made to FIG. 9, which is a simplified flow diagram illustrating the algorithm of the decoder of FIG. 8.

Iterative decoding of the input is carried out in individual stages in the conventional manner but in conjunction with the following: preferably, the bit reliability matrices employed by the iterative TBC decoder are converted into squared Euclidean distances at bit reliability converter 82, and an array of distances thereby obtained is denoted below as Y.

TBC decoder 84, applies A₁ (or A₂) to Y in order to produce output codewords. If the output of A₁ (or A₂) is a legitimate codeword ĈεCₚ, then the iterative process is ended and Ĉ is output as a final result. On the other hand, if a legitimate codeword is not produced then iteration is continued.

It is noteworthy that B, with the application of iteration aborter 80, may contain a large number of “bit errors” and still be decoded correctly to Ĉ. Thus, more than merely an iteration stopping method, this scheme inherently speeds up the decoding process as a result of its bounded-distance property. Due to this property any point Y within a sphere of radius \sqrt{dᵣd_{c}} about some codeword Ĉ will be mapped directly to Ĉ within a single application of A₁ (or A₂). It is important to note that the complexity involved in the implementation of iteration abort method is proportional to n, rather than n², which is the coinvolved in a single iteration of the iterative decoder. Moreover, most of the computations required for the presently described implementation are performed by the iterative decoder in any case, and hence the additional complexity of A₁ (or A₂), when ‘inter-implemented’ with an iterative decoder, is negligible.

Thus, the present invention provides non-iterative decoders which can be used for decoding turbo block codes or for substantially reducing the iterative process in iterative decoders thus enabling rapid and accurate decoding of both short and long turbo block codes.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent, or patent application was specifically and individually indicated to be incorporated herein by reference. In addition, citation or identification of any reference in this application shall not be construed as an admission that such reference is available as prior art to the present invention.

What is claimed is:

1. A turbo block codes decoder for decoding turbo block codes being inputted in a matrix having at least two dimensions, the turbo block codes decoder comprising:
(a) a first decoder for soft decoding individual first block codes along a first dimension of the matrix for generating first codewords in said first dimension of the matrix;
(b) a reliability measure calculator for calculating reliability measures of said first codewords in said first dimension of the matrix, thereby forming soft valued vectors along a second dimension of the matrix; and
(c) a second decoder for soft decoding individual vectors of said soft valued vectors along said second dimension of the matrix, for generating second codewords in said second dimension of the matrix, said second codewords being a decoded output of the turbo block codes decoder.

2. The turbo block codes decoder of claim 1, further comprising:
(d) a declarator for declaring a decoding failure if said decoded output fails to comply with a legitimate codeword in said turbo block code.

3. The turbo block codes decoder of claim 1, further comprising:
(d) a first dimension syndrome calculator for determining whether decoded bits of said second codewords form legitimate codewords in said first dimension.

4. The turbo block codes decoder of claim 1, wherein said first dimension is a row dimension and said second dimension is a column dimension.

5. The turbo block codes decoder of claim 1, wherein said reliability measures of said first codewords in said first dimension of the matrix is given by: f(yᵢ−,ĉᵢ−) wherein, yᵢ− is a first dimension line j, ĉᵢ− is a first decoded codeword i, whereas f(yᵢ−,ĉᵢ−) is a function of the Euclidean distance between yᵢ− and ĉᵢ− as defined by: d(yᵢ−,ĉᵢ−).

6. The turbo block codes decoder of claim 5, wherein a bit reliability of a decoded bit i,j, ĉ_{i,j} of said first codeword ĉᵢ− is given by: F(yᵢ−,ĉᵢ−,ĉ_{i,j}), wherein said F(yᵢ−,ĉᵢ−,ĉ_{i,j}) is a finction of ĉ_{i,j} and a reliability f(yᵢ−,ĉᵢ−) of said first dimension line yᵢ−.

7. The turbo block codes decoder of claim 1, wherein said first decoder and said second decoder are the same decoder.

8. The turbo block codes decoder of claim 1, wherein said first decoder and said second decoder are different decoders.

9. A system of turbo block codes decoders comprising the turbo block codes decoder of claim 1, connected with a second identical turbo block codes decoder being designed and configured for decoding a transposition of said inputted matrix.

10. The system of claim 9, further comprising an output selector for selecting between the outputs of either one of said turbo block codes decoders.

11. The system of claim 9, further comprising an output selector for selecting between an output of either one of said turbo block codes decoders and an uncorrectable error flag.

12. The system of claim 11, wherein said output selector is operable to select according to the following rules:
(i) if only one of said turbo block codes decoders outputs a legitimate codeword—select said legitimate codeword; and
(ii) if both said turbo block codes decoders output legitimate codewords—select the output characterized by a minimum Euclidean distance from the inputted matrix.

13. The system of claim 12, wherein if neither of the outputs are legitimate codewords, said output selector is operable to indicate a decoding failure.

14. The system of claim 12, wherein if neither of the outputs are legitimate codewords, said output selector is operable to request reinput of the turbo block codes.

15. The system of claim 12, wherein if neither outputs are legitimate codewords, said output selector is operable to select the output having minimum Euclidean distance from inputted matrix.

16. The system of claim 12, wherein if neither outputs are legitimate codewords, said output selector is operable to select the output having fewer bit errors relative to a bit-wise hard decision decoding of the inputted matrix.

17. The system of claim 12, wherein if neither outputs are legitimate codewords, said output selector is operable to select a combination of bits from the two outputs to form an optimized combination result.

18. A system for turbo block codes decoding, comprising an iterative turbo block decoder and the turbo block codes decoder of claim 1, being connected thereto and operable to supply said iterative turbo block decoder with a signal to perform a further decoding iteration whenever an output of said iterative turbo block decoder does not give rise to a legitimate codeword in said turbo block codes decoder.

19. A turbo block codes decoder for decoding turbo block codes being inputted in a matrix having at least two dimensions, the turbo block codes decoder comprising:
(a) a first decoder for soft decoding individual first block codes along a first dimension of the matrix for generating first codewords in said first dimension of the matrix;
(b) a first reliability measure calculator for calculation a reliability of said first codewords in said first dimension of the matrix, thereby forming first soft valued vectors along a second dimension of the matrix;
(c) a second decoder for soft decoding individual vectors of said first soft valued vectors along said second dimension of the matrix for generating second codewords in said second dimension of the matrix, said second codewords being a first decoded candidate output of the turbo block codes decoder;
(d) a third decoder for soft decoding individual second block codes along said second dimension of the matrix for generating third codewords in said second dimension of the matrix;
(e) a second reliability measure calculator for calculation a reliability of said third codewords in said second dimension of the matrix, thereby forming second soft valued vectors along said first dimension of the matrix;
(f) a fourth decoder for soft decoding individual vectors of said second soft valued vectors along said first dimension of the matrix for generating fourth codewords in said first dimension of the matrix, said fourth codewords being a second decoded candidate output of the turbo block codes decoder; and
(g) a selector for selecting among said first and said second decoded candidate outputs.

20. The turbo block codes decoder of claim 19, wherein said first decoder, said second decoder, said third decoder and said fourth decoder are each a different decoder.

21. The turbo block codes decoder of claim 19, wherein at least two of said first decoder, said second decoder, said third decoder and said fourth decoder are identical decoders.

22. The turbo block codes decoder of claim 19, wherein said first reliability measure calculator and said second reliability measure calculator are identical reliability measure calculators.

23. The turbo block codes decoder of claim 19, wherein said first reliability measure calculator and said second reliability measure calculator are different reliability measure calculators.

24. The turbo block codes decoder of claim 19, wherein said first decoder, said second decoder and said first reliability measure calculator form a first turbo block codes decoder unit of said turbo block codes decoder, whereas said third decoder, said fourth decoder and said second reliability measure calculator form a second turbo block codes decoder unit of said turbo block codes decoder.

25. The turbo block codes decoder of claim 24, wherein said selector is for selecting among said first and said second decoded candidate outputs and an uncorrectable error flag.

26. The turbo block codes decoder of claim 24, wherein said output selector is operable to select according to the following rules:
(i) if only one of said turbo block codes decoder units outputs a legitimate codeword—select said legitimate codeword; and
(ii) if both said turbo block codes decoder units output legitimate codewords—select the output characterized by a minimum Euclidean distance from the inputted matrix.

27. The turbo block codes detector of claim 26, wherein if neither outputs are legitimate codewords, said output selector is operable to indicate a decoding failure.

28. The turbo block codes detector of claim 26, wherein if neither of the outputs are legitimate codewords, said output selector is operable to request reinput of the turbo block codes.

29. The turbo block codes detector of claim 26, wherein if neither outputs are legitimate codewords, said output selector is operable to select the output having minimum Euclidean distance from the inputted matrix.

30. The turbo block codes detector of claim 26, wherein if neither outputs are legitimate codewords, said output selector is operable to select the output having fewer bit errors relative to a bit-wise hard decision decoding of the inputted matrix.

31. The turbo block codes detector of claim 26, wherein if neither outputs are legitimate codewords, said output selector is operable to select a combination of bits from the two outputs to form an optimized combination result.

32. A turbo-block codes decoder comprising a non-iterative decoder and an iterative decoder connected such that an output at each step of the iterative decoder is used as an input to the non-iterative decoder to produce an output matrix, wherein said non-iterative decoder is operable to determine whether said output matrix is a legitimate codeword of a turbo-block code being used, and further wherein a result of said determination signals said iterative decoder to carry out a further iteration step if said output matrix is not a legitimate codeword.

33. The turbo-block codes decoder of claim 32, wherein the non-iterative decoder including:
(a) a first decoder for soft decoding individual first block codes along a first dimension of the matrix for generating first codewords in said first dimension of the matrix;
(b) a reliability measure calculator for calculating reliability measures of said first codewords in said first dimension of the matrix, thereby forming soft valued vectors along a second dimension of the matrix; and
(c) a second decoder for soft decoding individual vectors of said soft valued vectors along said second dimension of the matrix, for generating second codewords in said second dimension of the matrix, said second codewords being a decoded output of the turbo block codes decoder.

34. The turbo-block codes decoder of claim 33, wherein the non-iterative decoder further including:
(d) a declarator for declaring a decoding failure if said decoded output fails to comply with a legitimate codeword in said turbo block code.

35. The turbo-block codes decoder of claim 33, wherein the non-iterative decoder further including:
(d) a first dimension syndrome calculator for determining whether decoded bits of said second codewords form legitimate codewords in said first dimension.

36. A method of decoding turbo block codes being inputted in a matrix having at least two dimensions, the method comprising the steps of:
(a) decoding individual first block codes along a first dimension of the matrix for generating first codewords in said first dimension of the matrix;
(b) calculating reliability measures of said first codewords in said first dimension of the matrix, thereby forming soft valued vectors along a second dimension of the matrix; and
(c) soft decoding individual vectors of said soft valued vectors along said second dimension of the matrix, for generating second codewords in said second dimension of the matrix, said second codewords being a first decoded candidate output.

37. The method of claim 36, further comprising the step of.
(d) declaring a decoding failure if said decoded candidate output fails to comply with a legitimate codeword in said turbo block codes.

38. The method of claim 36, further comprising the step of:
(d) determining whether decoded bits of said second codewords form legitimate codewords in said first dimension.

39. The method of claim 36, wherein said first dimension is a row dimension and said second dimension is a column dimension.

40. The method of claim 36, wherein said reliability measures of said first codewords in said first dimension of the matrix is given by: f(yᵢ−,ĉᵢ−), wherein yᵢ− is a first dimension line i, ĉᵢ−is a first codeword i, whereas f(yᵢ−,ĉᵢ−) is a function of an Euclidean distance between yᵢ− and ĉᵢ− as defined by: d(yᵢ−,ĉᵢ−).

41. The method of claim 40, wherein a bit reliability of a decoded bit i,j, ĉ_{i,j} of said first codeword ĉᵢ− is given by: F(yᵢ−,ĉᵢ−ĉ_{i,j}), wherein said F(yᵢ−,ĉᵢ−,ĉ_{i,j}) is a function of ĉ_{i,j} and a reliability f(yᵢ−,ĉᵢ−) of said first dimension line yᵢ−.

42. The method of claim 34, further comprising the steps of:
(d) transposing the matrix and repeating steps (a)-(c) to thereby generate a second decoded candidate output.

43. The method of claim 42, further comprising the step of:
(e) selecting among said first and said second decoded candidate outputs.

44. The method of claim 42, further comprising the step of:
(e) selecting among said first and said second decoded candidate outputs and an uncorrectable error flag.

45. The method of claim 42, further comprising the step of:
(e) indicating a decoding failure if neither decoded candidate outputs are legitimate codewords.

46. The method of claim 42, further comprising the step of:
(e) request reinput of the turbo block codes if neither of the decoded candidate outputs are legitimate codewords,.

47. The method of claim 42, further comprising the step of:
(e) selecting said decoded candidate output having minimum Euclidean distance from the turbo block codes inputted in the matrix if neither of the outputs are legitimate codewords.

48. The method of claim 42, further comprising the step of:
(e) selecting said decoded candidate output having fewer bit errors relative to a bit-wise hard decision decoding of the inputted matrix if neither outputs are legitimate codewords.

49. The method of claim 42, further comprising the step of:
(e) selecting a combination of bits from said first and said second decoded candidate outputs to form an optimized combination result if neither outputs are legitimate codewords.

50. The method of claim 36, wherein step (b) is effected according to the following rules:
(i) if only one of said turbo block codes decoder units outputs a legitimate codeword—select said legitimate codeword; and
(ii) if both said turbo block codes decoder units output legitimate codewords—select the output characterized by a minimum Euclidean distance from the inputted matrix.

51. A method for iteratively decoding a turbo block encoded message, the method comprising the steps of:
(a) carrying out an iterative turbo-block decoding step to produce a first output;
(b) decoding said first output non-iteratively to produce an output matrix; and
(c) determining whether said output matrix is a legitimate codeword in said turbo block code.

52. The method of claim 51, further comprising the step of:
(d) returning to said iterative decoding step if said output matrix is not legitimate or terminating said iterative decoding if said output matrix is a legitimate codeword in said turbo block code.
